(19) United States
(12) Patent Application Publication
(10) Pub. No.: US 2012/0049316 A1
(43) Pub. Date: Mar. 1, 2012

(54) THERMOELECTRIC MODULE AND METHOD FOR FABRICATING THE SAME

(75) Inventors: Yong Suk KIM, Gyeonggi-do (KR); Sung Ho Lee, Gyeonggi-do (KR); Yong Soo Oh, Gyeonggi-do (KR); Tae Kon Koo, Seoul (KR)

(73) Assignee: SAMSUNG Electro-Mechanics Co., Ltd.

(21) Appl. No.: 13/219,156

(22) Filed: Aug. 26, 2011

(30) Foreign Application Priority Data
Aug. 27, 2010 (KR) 10-2010-0083372

(51) Int. Cl. H01L 31/058; H01L 31/18

(52) U.S. Cl. 257/467; 438/54; 257/E31.054

(57) ABSTRACT

The present invention provides a thermoelectric module. The thermoelectric module includes a first substrate and a second substrate opposed to each other and arranged to be separated from each other, a first electrode and a second electrode arranged in the inside surfaces of the first and the second substrates, respectively, and a thermoelectric device inserted between the first and the second electrodes and electrically connected to the first and the second electrodes, wherein surface improvement layers are further included in at least one place located between an inside surface of the first substrate and the first electrode, between an inside surface of the second substrate and the second electrode, on an outside surface of the first substrate and on an outside surface of the second substrate.

### CROSS-REFERENCE TO RELATED APPLICATIONS

This application claims the benefit of Korean Patent Application No. 10-2010-0083372 filed with the Korea Intellectual Property Office on Aug. 27, 2010, the disclosure of which is incorporated herein by reference.

### BACKGROUND OF THE INVENTION

1. Field of the Invention

The present invention relates to a thermoelectric module and a method for fabricating the same.

2. Description of the Related Art

The thermoelectric module can operate as a solid state heat pump and utilize as a cooler or a heater. Since the thermoelectric module has high reliability with a simple structure and without mechanical operational elements, it has advantages of low noise and vibration as well as miniaturization in comparison with a conventional cooler using such as a compressor.

Also, the thermoelectric module is capable of performing rapid and accurate temperature control and cooling/heating conversion with simple operation, thereby applying to a high precise cooler/thermostat, an optical element device, an optical sensor and precise electric products.

Also, since the thermoelectric module realizes cooling and heating at the same time in one module by changing the polarity of direct power, it can be effectively utilized for an air handling unit or the like. It can be utilized for the other product, for example, a compact cooling device, a cosmetic refrigerator, a wine refrigerator, a hot and cold water purifier, a cooling sheet for vehicles, semiconductor equipment and a cooling/thermostat device such as a precision thermostat chamber.

In order to fabricate such thermoelectric module, the size of device, characteristics, junction and packaging and the like become main issues. According to the design of the module and the manufacturing method, the characteristics of the thermoelectric module can be determined along with the characteristics and durability, reliability and the other environments.

In the conventional method, the thermoelectric module is formed by joining the thermoelectric device on a flat substrate, at this time; an incomplete junction is generated by the non-uniformity of the substrate thickness or the accuracy failure of patterns, thereby generating a local junction failure and the increment of contact resistance.

Such module generates efficiency degradation including the performance index of the thermoelectric module and deterioration due to thermal shock and moisture, thereby causing the reliability deterioration or the like.

### SUMMARY OF THE INVENTION

The present invention has been proposed in order to overcome the above-described problems and it is, therefore, an object of the present invention to provide a thermoelectric module and a method for fabricating the same capable of solving problems such as a local junction failure due to incomplete junction and the increment of contact resistance to be generated by the non-uniformity of substrate thickness or the inaccuracy of patterns; and, more particularly problems such as the local junction failure and the increment of contact resistance by inserting the surface improvement layers between the substrates and the electrode patterns.

In accordance with one aspect of the present invention to achieve the object, there is provided a thermoelectric module including a first substrate and a second substrate opposed to each other and arranged to be separated from each other, a first electrode and a second electrode arranged in the inside surfaces of the first and the second substrates, respectively, and a thermoelectric device inserted between the first and the second electrodes and electrically connected to the first and the second electrodes, wherein surface improvement layers are further included in at least one place located between an inside surface of the first substrate and the first electrode, between an inside surface of the second substrate and the second electrode, on an outside surface of the first substrate and an outside surface of the second substrate.

Herein, the surface improvement layers are enamel layers and the enamel layers include a first layer provided with cobalt oxide or lead oxide and a second layer provided with titanium oxide or antimony oxide.

At this time, a ratio between the first and the second layers is from 1:2 to 1:3.

Herein, the first and the second substrates may be one of a ceramic substrate, a metal substrate and a polymer substrate and the polymer substrate is made of anyone of polyimide, Tefron, epoxy, PMMA, and PP.

Herein, thermal grease may be further inserted between the thermoelectric device and the first electrode or the thermoelectric device and the second electrode.

Herein, the thermoelectric device is connected to the first and the second electrodes, respectively, by solders.

In accordance with another aspect of the present invention to achieve the object, there is provided a method for fabricating a thermoelectric module including the steps of: preparing a first substrate and a second substrate; forming surface improvement layers in at least one surface located between an inside surface of the first substrate and a first electrode, between an inside surface of the second substrate and a second electrode, on an outside surface of the first substrate and an outside surface of the second substrate; arranging the first electrode, a first solder layer and a thermoelectric device on the inside surface of the first substrate by stacking them; arranging the second electrode and the second solder layer corresponding to the thermoelectric device on the inside surface of the second substrate by stacking them; and positioning the second substrate on the first substrate and forming the thermoelectric device by connecting the first and the second electrodes to the thermoelectric device by the first and the second solder layers through a reflow process.

Herein, the step of forming the surface improvement layers is a step of forming enamel layers.

At this time, the enamel layers include a first layer provided with cobalt oxide or lead oxide and a second layer provided with titanium oxide or antimony oxide, wherein the second layer is formed after the first layer is formed.

Also, after the enamel layers are cleaned and dried at least one surface among the inside surface of the first substrate, the outside surface of the first substrate, the inside surface of the second substrate and the outside surface of the second substrate through a wet or a dry process, after, on said at least one surface, material consisting of the first layer or the second layer is coated in a shape of a slurry or a paste, forming the enamel layers by performing a sintering process and the annealing is performed at a temperature ranging from 800 degrees to 920 degrees.

Also, the enamel layers are formed by forming the first layer or the second layer in a shape of thin film on at least one among the inside surface of the first substrate, the outside surface of the first substrate, the inside surface of the second substrate and the outside surface of the second substrate by using a physical vapor deposition method or a chemical vapor deposition method.

Herein, thermal grease can be further formed between the thermoelectric device and the first electrode and the thermoelectric device and the second electrode.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view showing a thermoelectric module in accordance with one embodiment of the present invention; and

FIGS. 2 to 5 are cross-sectional views showing a method for fabricating a thermoelectric module in accordance with another embodiment of the present invention.

### DETAILED DESCRIPTION OF THE PREFERABLE EMBODIMENTS

Embodiments of the present invention will be described in detail with reference to the accompanying drawings. The embodiments described hereinafter will be provided as examples so that the scope of the invention is fully conveyed to those skilled in the art.

Therefore, this invention may be embodied in many different forms and should not be construed as limited to the exemplary embodiments set forth herein. And, in the drawings, the size and relative sizes of layers and regions may be exaggerated for clarity. Like reference numerals in the drawings denote like elements.

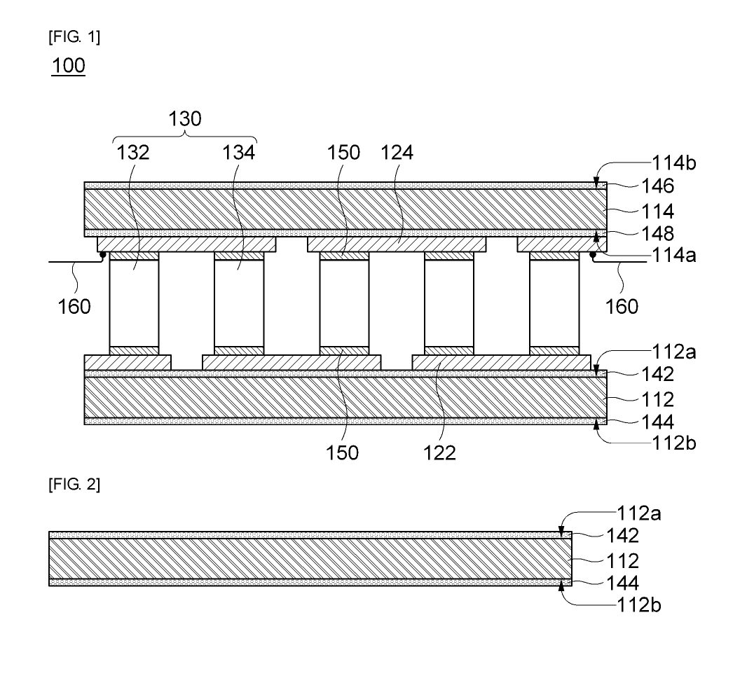

FIG. 1 is a cross-sectional view showing a thermoelectric module in accordance with one embodiment of the present invention.

Referring to FIG. 1, a thermoelectric module 100 in accordance with the present invention includes a first substrate 112 and a second substrate 114 separated with opposing to each other, a first electrode 122 and a second electrode 124 inserted inside surfaces 112a and 114a of the first and second substrates 112 and 114 and a thermoelectric device 130 inserted between the first and second substrate 112 and 114.

Also, the thermoelectric module 100 may include surface improvement layers on anyone surface among an inside surface 112a of the first substrate 112, an outside surface of the first substrate 112, and inside surface 114a of the second substrate 114 and an outside surface 114b of the second substrate 114. In FIG. 1, although there is shown that a first surface improvement layer 142, a second surface improvement layer 144, a third surface improvement layer 146 and a fourth surface improvement layer 146 are formed on the inside surface 112a of the first substrate 112, the outside surface of the first substrate 112, the inside surface 114a of the second substrate 114 and the outside surface 115b of the second substrate 114, respectively, anyone surface improvement layer may be omitted. And also, in FIG. 1, although the surface improvement layers are not formed on the four side surfaces of the first substrate 112 and the four side surfaces of the second substrate 114, the surface improvement layers may be formed on the four side surface of the first substrate 112 and the four side surfaces of the second substrate 114 if necessary. At this time, the four side surfaces of the first substrate 112 and the four side surfaces of the second substrate 114 mean four inside surfaces of the first substrate 112 and four side surfaces of the second substrate 114 except for the inside surfaces and the outside surfaces of each substrate as shown in FIG. 1.

The surface improvement layers 142, 144, 146 and 148 may be enamel layers. The enamel layers may include a first layer provided with cobalt oxide or lead oxide and a second layer provided with titanium oxide or antimony oxide. The enamel layer may be formed by forming the first layer and forming the second layer. At this time, a ratio between the first and the second layers of the enamel layer can be formed in a thickness ratio from 1:2 to 1:3.

By inserting the surface improvement layers 142 and 146 between the first and second substrates 112 and 114 and the first and second electrodes 122 and 124, the connection strength between the first and second substrates 112 and 114 and the first and second electrodes 122 and 124 and the interface portions between the first and second substrates 112 and 114 and the first and second electrodes 122 and 124 are maintained without being damaged to thereby have an effect to improve the tolerance of the thermoelectric module 100.

And also, by forming the surface improvement layers 144 and 148 on the external surfaces of the first and second substrates 112 and 114, the corrosion resistance can be obtained even in environments such as the gas exposure such as CO₂ and NO_{X} or the like and a high temperature and humidity or the like as well as there are advantages that the thermal resistance and the surface strength are excellent and the thermoelectric module has high resistance to the thermal shock of a high temperature part or a low temperature part.

And also, the surface improvement layers 142, 144, 146 and 148 can remove the difficulties such as the increment of manufacturing cost according to the process to remove foreign materials or the deterioration of yields due to the foreign materials in forming the first and second electrodes 122 and 124 since they have self cleaning functions.

Pigments can be included in the surface improvement layer 142 on the outside surface 112b of the first substrate 112 or the surface improvement layer 144 on the outside surface 114b of the second substrate 114. The pigments make the surface improvement layers 142 and 144 show various colors, and particularly represent an advertisement effect by inserting logos or pictures or the like.

The first and second substrates 112 and 114 can play a role of supporting the thermoelectric device 130 and the first and second electrodes 122 and 124. Further, when the thermoelectric device 130 is formed by a plurality of pieces, the first and second substrates 112 and 114 can perform the role of connecting the plurality of thermoelectric devices 130.

And also, the first substrate 112 and the second substrate 114 can play the role of absorbing heat from outside or discharging the heat to the outside through the heat exchange of the thermoelectric device 130 by being connected to an external apparatus. That is, the first substrate 112 and the second substrate 114 can play the role of performing the heat exchange between the external apparatus and the thermoelectric device 130. Therefore, the efficiency of the thermoelectric module 100 can be affected by the thermal conductivity of the first and second substrates 112 and 114.

In order to this, the first and second substrates 112 and 114 can be made of ceramic having high thermal conductivity.

Also, the first and second substrates 112 and 114 can be made of metal having excellent thermal conductivity. For example, the first and second substrates 112 and 114 can be made of aluminum and copper or the like. In this result, the thermoelectric efficiency can be improved by allowing the first and second substrates 112 and 114 to have excellent thermal conductivity.

At this time, between the inside surfaces 112a and 114a of the first substrate 112 and the second substrate 114, specifically between the first substrate 112 and the first surface improvement layer 142 and between the second substrate 114 and the third surface improvement layer 146, the electric insulating property of the first and second substrates 112 and 114 can be endowed by arranging the insulating layer (not shown) to insulate between the first and second substrates 112 and 114 made of metal and the first and second electrodes 122 and 124. At this time, the insulating layer can be made of material having durability capable of withstanding the process to form the thermoelectric module 100. For example, the insulating layer can be made of anyone among SiO₂, Al₂O₃, TiO₂, ZnO, NiO and Y₂O₃.

Herein, the insulating layer can be formed in a thickness ranging from 0.2 μm to 10 μm. If the thickness of the insulating layer is below 0.2 μm, it is difficult to secure the insulation property. Whereas, if the thickness of the insulating layer is above 10 μm, it can deteriorate the thermal conductivity between the first substrate 112 or the second substrate 114 and the thermoelectric device 130.

Further, the insulating layer can play a role of securing the insulation property of the first substrate 112 and the second substrate 114 as well as it can further perform a role of filling air gaps formed in the first substrate 112 and the second substrate 114. Hereby, it can prevent the heat transmission from being deteriorated by the air gaps between the first substrate 112 and the first electrode 122 and between the second substrate 114 and the second electrode 122.

Also, the first and second substrates 112 and 114 may be a polymer substrate. For example, the first and second substrates 112 and 114 can be made of polymer, Tefron, epoxy, PMMA, and PP or the like and the thermoelectric module 100 which is flexible by being made of the polymer can be supplied.

On the other hand, the thermoelectric device 130 can include a P-type semiconductor 132 and an N-type semiconductor 134. At this time, the P-type semiconductor 132 and the N-type semiconductor 134 can be alternatively arranged on the same plane.

At this time, the first and second electrodes 122 and 124 can be arranged to face each other with placing the thermoelectric device 130 therebetween. At this time, a pair of P-type semiconductor 132 and N-type semiconductor 134 are electrically connected by the first electrode 122 placed at the bottom surface therebelow and another pair of neighboring P-type semiconductor 132 and the N-type semiconductor 134 can be electrically connected by the second electrode 124 located on the top surface thereof.

The first electrode 122 and the second electrode 124 and the thermoelectric device 130 can be connected to each other by a solder 150. Herein, the solder 150 can include Sn such as PbSn or CuAgSn.

In addition, the first and second electrodes 122 and 124 can supply power to an external power unit or receive power by being connected to the external power unit through a wire 160. That is, if the thermoelectric module 100 plays a role of a generating apparatus, the power can be supplied to the external power unit, and if it plays a role of a cooling apparatus, the power can be received from the external power unit.

Also, not shown in the drawings, thermal grease can be inserted between the thermoelectric device 130 and the first electrode 122 or the thermoelectric device 130 and the second electrode 122. Herein, the thermal grease plays the role of filling the air gaps formed in each boundary surface, thereby playing a role to prevent the thermal conductivity from being deteriorated by the air gaps.

FIGS. 2 to 5 are cross-sectional views showing a method for fabricating a thermoelectric module in accordance with another embodiment of the present invention.

Referring to FIGS. 2 to 5, the method for fabricating the thermoelectric module in accordance with one embodiment of the present invention will be explained in detail

Referring to FIG. 2, in order to fabricate the thermoelectric module, a first substrate 112 is prepared at first.

The first substrate 112 may be a ceramic substrate made of ceramic.

And also, the first substrate 112 may be a metal substrate made of metal material having excellent thermal conductivity, if the first substrate 112 is made of metal material, an insulating layer (not shown) can be formed on the inside surface of the first substrate 112.

The insulating layer can be made of anyone among SiO₂, Al₂O₃, TiO₂, ZnO, NiO and Y₂O₃. Herein, one example of methods for forming the insulating layer is a printing method, an ALD (Atom Layer Deposition) method, a sputtering method, an E-beam method and a CVD (Chemical Vapor Deposition) method or the like, and the insulating layer can be formed in a thickness ranging from 0.2 μm to 10 μm considering on the effect to the secured insulation and thermal conductivity.

Also, the first substrate 112 may be a polymer substrate. For example, the first substrate 112 may be made of polymer, Tefron, epoxy, PMMA, and PP or the like.

The first surface improvement layer 142 and the second surface improvement layer 144 are formed on the inside surface 112a and the outside surface 112b of the first substrate 112. As described above, anyone of the first surface improvement layer 142 and the second surface improvement layer 144 may be omitted and both can be omitted if necessary.

Herein, the first and second surface improvement layers 142 and 144 are formed after at least one surface among the inside surface 112a and the outside surface 112b of the first substrate 112 is cleaned and dried by a wet or a dry method. At this time, the first and second surface improvement layers 142 and 144 can be made of an enamel layer including a first layer with cobalt oxide or lead oxide and a second layer with titanium oxide or antimony oxide, the first layer is formed at first, and then, the second layer is formed to form the enamel layer. At this time, the process to clean using the dry method can be performed such as a plasma treatment, and the process to clean using the wet method can be cleaned with ultra pure water or, after cleaned with acid or basic solution, cleaned with the ultra pure water.

Meanwhile, if the first substrate 112 is the ceramic substrate or the metal substrate, the first and second surface improvement layers 142 and 144, after the material consisting the first layer or the second layer in a shape of slurry or paste, can be formed by coating and sintering these. At this time, the sintering process can be performed at a temperature ranging from 800° C. to 920° C.

If the first substrate 112 is a polymer substrate, the material consisting the first layer and the second layer can be formed by sequentially coating or depositing using a printing method such as a liquid phase coating method, a chemical vapor deposition method such as PECVD or a physical vapor deposition method such as an ALD method, a sputtering method and an E-beam method.

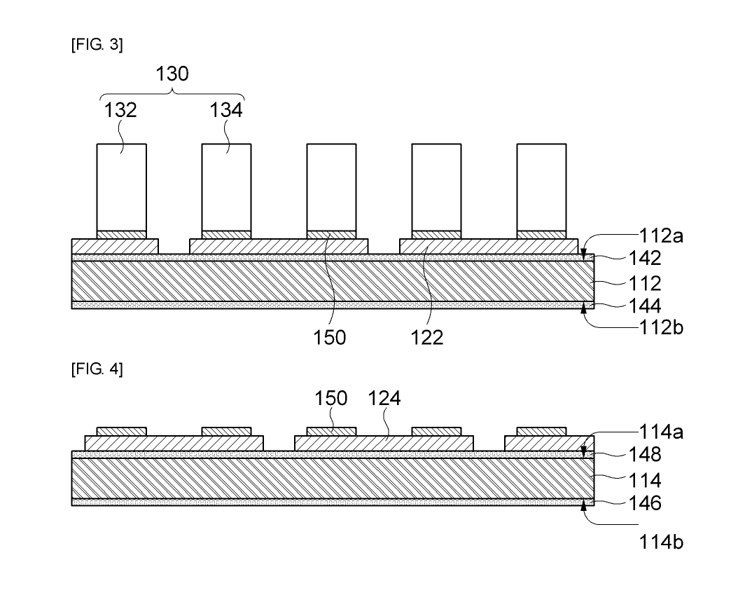

Referring to FIG. 3, thereafter, the first electrode 122 is formed on the inside surface 112a of the first substrate 112, preferably on the surface improvement layer 142 on the inside surface 112a. Herein, the first electrode 122, after the conductive layer is formed by depositing the conductive material, can be formed by patterning the conductive layer. However, in the embodiment of the present invention, it does not limit to this; for example, the first electrode 122 can be formed through a plating process and a printing process or the like.

And then, the first solder layer 150a is formed on the first electrode 122. The first solder layer 150 can be formed by printing the conductive paste including Sn such as PbSn or CuAgSn.

And then, the thermoelectric device 130 is formed on the first solder layer 150. Herein, the thermoelectric device 130 can include a P-type semiconductor 132 and an N-type semiconductor 134, at this time the P-type semiconductor 132 and the second surface improvement layer 134 can be exchanged alternately.

Referring to FIG. 4, a second substrate 114 is prepared separately from a process of forming a first surface improvement layer 142, a second surface improvement layer 144, a first electrode 122, a solder layer 150a and a thermoelectric device 130 on a first substrate 112.

Thereafter, since a third surface improvement layer 144 and a fourth surface improvement layer 148 can be formed by using the same method as the first surface improvement layer 142 and the second surface improvement layer 144 are formed on an inside surface 114 and an outside surface 114b of the second substrate 114 and on an inside surface 112a and an outside surface 112b of the first substrate 112, the detail description for the method of forming the third surface improvement layer 146 and the fourth surface improvement layer 148 will be omitted.

And then, a process of forming the second electrode 124 and the second solder layer 150 on the inside surface 114a of the second substrate 113, precisely on the third surface improvement layer 146.

At this time, the second substrate 114 may be the ceramic substrate made of ceramic and the polymer substrate identical to the first substrate 112, may be made of metal material having excellent thermal conductivity, if the second substrate 114 is made of metal material, an insulating layer (not shown) can be formed on the inside surface of the second substrate 114.

The second electrode 124 and the second solder layer 150b are sequentially formed on the inside of the second substrate 114. Herein, the second electrode 124 and the second solder layer 150b may be the same material of the first electrode 122 and the first solder layer 150a and can be formed by the same forming method.

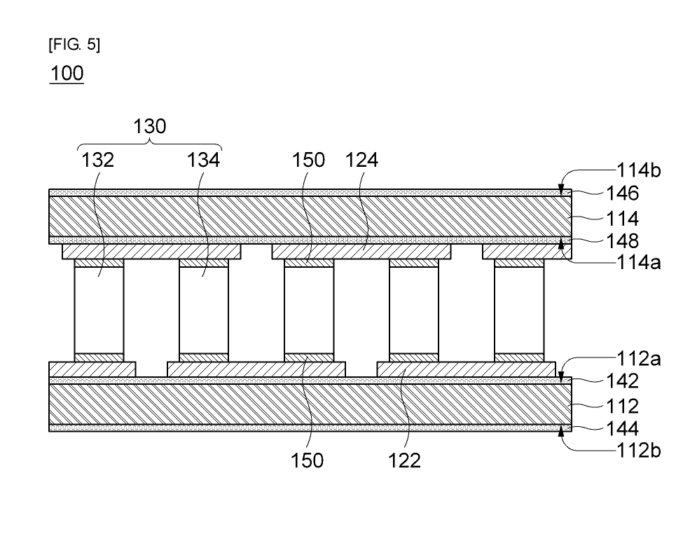

Referring to FIG. 5, after the second substrate 114 is arranged on the first substrate 112 so as to allow the thermoelectric device 130 and the second electrode 124 to be contact with each other, if a predetermined pressure is applied to the second substrate 114 or the first substrate 112, the thermoelectric module 100 can be fabricated by connecting the thermoelectric device 130 to the first and second electrodes 122 and 124 through a reflow process.

In addition, although not shown in the drawings, thermal grease can be further formed on anyone places located between the thermoelectric device 130 and the first electrode 122 and between the thermoelectric device 130 and the second electrode 124.

In addition, although not shown in the drawings, in order to connect the wire 160 to each of the first electrode 122 and the second electrode 124 similar to the thermoelectric module 100 as shown in FIG. 1, a process to connect the wire 160 to the first electrode 122 and the second electrode 124 can be proceeded.

The thermoelectric modules in accordance with the embodiments of the present invention improve the adhesive strength between the substrate and the electrode patterns by inserting the surface improvement layers between the substrate and the electrode patterns, thereby improving the durability of the thermoelectric module.

Also, the thermoelectric modules in accordance with the embodiments of the present invention can secure the corrosion resistance even in environments such as the gas exposure such as CO₂ and NO_{X} or the like and a high temperature and humidity or the like as well as maintain the interface parts between the substrate and the electrode patterns or the like without being damaged.

Also, the thermoelectric modules in accordance with the embodiments of the present invention have advantages that the thermal resistance and the surface strength are excellent and they have high resistance to the thermal shock of a high temperature part or a low temperature part.

Also, the thermoelectric modules in accordance with the embodiments of the present invention have advantages that the difficulties due to foreign materials in the processes can be removed since the self cleaning functions exist in the surface improvement layers.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A thermoelectric module comprising:
a first substrate and a second substrate opposed to each other and arranged to be separated from each other;
a first electrode and a second electrode arranged in the inside surfaces of the first and the second substrates, respectively; and
a thermoelectric device inserted between the first and the second electrodes and electrically connected to the first and the second electrodes,
wherein surface improvement layers are further included in at least one place located between an inside surface of the first substrate and the first electrode, between an inside surface of the second substrate and the second electrode, on an outside surface of the first substrate and on an outside surface of the second substrate.

2. The thermoelectric module of claim 1, wherein the surface improvement layers are enamel layers.

3. The thermoelectric module of claim 2, wherein the enamel layers include a first layer provided with cobalt oxide or lead oxide and a second layer provided with titanium oxide or antimony oxide.

4. The thermoelectric module of claim 3 wherein a ratio between the first and the second layers is from 1:2 to 1:3.

5. The thermoelectric module of claim 1, wherein the first and the second substrates are material selected from a group consisting of a ceramic substrate, a metal substrate and a polymer substrate.

6. The thermoelectric module of claim 5, wherein the polymer substrate is made of anyone of polyimide, Tefron, epoxy, PMMA, and PP.

7. The thermoelectric module of claim 1, further comprising thermal grease between the thermoelectric device and the first electrode or the thermoelectric device and the second electrode.

8. The thermoelectric module of claim 1, wherein the thermoelectric device is connected to the first and the second electrodes, respectively, by solders.

9. The thermoelectric module of claim 1, wherein pigments are further included in the surface improvement layers which are formed on the outside surface of the first substrate and the outside surface of the second substrate.

10. The thermoelectric module of claim 1, wherein the surface improvement layers are formed on four side surfaces of the first substrate and on four side surfaces of the second substrate.

11. A method for fabricating a thermoelectric module comprising the steps of:
preparing a first substrate and a second substrate;
forming surface improvement layers in at least one surface located between an inside surface of the first substrate and a first electrode, between an inside surface of the second substrate and a second electrode, on an outside surface of the first substrate and an outside surface of the second substrate;
arranging the first electrode, a first solder layer and a thermoelectric device on the inside surface of the first substrate by stacking them;
arranging the second electrode and the second solder layer corresponding to the thermoelectric device on the inside surface of the second substrate by stacking them; and
positioning the second substrate on the first substrate and forming the thermoelectric device by connecting the first and the second electrodes to the thermoelectric device by the first and the second solder layers through a reflow process.

12. The method of claim 11, wherein the step of forming the surface improvement layers is a step of forming enamel layers.

13. The method of claim 12, wherein the enamel layers includes a first layer provided with cobalt oxide or lead oxide and a second layer provided with titanium oxide or antimony oxide, wherein the second layer is formed after the first layer is formed.

14. The method of claim 13, wherein after the enamel layers are cleaned and dried at least one surface among the inside surface of the first substrate, the outside surface of the first substrate, the inside surface of the second substrate and the outside surface of the second substrate through a wet or a dry process,
after, on said at least one surface, material consisting of the first layer or the second layer is coated in a shape of a slurry or a paste,
forming the enamel layers by performing a sintering process.

15. The method of claim 14, wherein the annealing is performed at a temperature ranging from 800 degrees to 920 degrees.

16. The method of claim 13, wherein the enamel layers are formed by forming the first layer or the second layer in a shape of thin film on at least one among the inside surface of the first substrate, the outside surface of the first substrate, the inside surface of the second substrate and the outside surface of the second substrate by using a physical vapor deposition method or a chemical vapor deposition method.

17. The method of claim 11, further comprising thermal grease between the thermoelectric device and the first electrode and the thermoelectric device and the second electrode.
